(19) United States
(12) Patent Application Publication
(10) Pub. No.: US 2025/0022860 A1
(43) Pub. Date: Jan. 16, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: Chengtar Wu, Suwon-si (KR)

(21) Appl. No.: 18/436,034

(22) Filed: Feb. 8, 2024

(30) Foreign Application Priority Data
Jul. 14, 2023 (KR) 10-2023-0091955

(51) Int. Cl. H01L 25/16; H01L 21/56; H01L 23/00; H01L 23/31; H01L 23/498; H01L 23/538; H10B 80/00

(52) U.S. Cl. CPC H01L 25/16; H01L 21/568; H01L 23/3121; H01L 23/49811; H01L 23/5383; H01L 24/16; H01L 24/32; H01L 24/73; H10B 80/00; H01L 2224/16227; H01L 2224/32225; H01L 2224/73204

(57) ABSTRACT

A semiconductor package according to an embodiment includes an interposer including a power distribution structure, and a redistribution structure on the power distribution structure; a first semiconductor die on the interposer; and a second semiconductor die on the interposer, wherein the power distribution structure may include a power distribution module connected to the bottom surface of the redistribution structure; a plurality of conductive posts connected to the bottom surface of the redistribution structure; and a molding material for molding the power distribution module and the plurality of conductive posts.

### CROSS-REFERENCE TO RELATED APPLICATION

This application claims priority to and the benefit thereof under 35 U.S.C. § 119 to Korean Patent Application No. 10-2023-0091955, filed Jul. 14, 2023, in the Korean Intellectual Property Office, the entire contents of which are incorporated herein by reference.

### BACKGROUND OF THE DISCLOSURE

### (a) Field of the Disclosure

The present disclosure relates to a semiconductor package and a manufacturing method thereof.

### (b) Description of the Related Art

As a device for supplying a power to semiconductor chips in a semiconductor package, a power distribution module (PDM) is used. The power distribution module (PDM) has a function of distributing a single power supply supplied from the outside of the semiconductor package differently according to the semiconductor chips and supplying the distributed power to each of the semiconductor chips.

Meanwhile, since the semiconductor chips have a fine pitch I/O, to be electrically connected to a substrate having a normal pitch I/O, an interposer is required as an intermediary between the semiconductor chips and the substrate. Therefore, conventionally, since the power distribution module (PDM) was disposed on the substrate, and the power distributed from the power distribution module (PDM) reaches the individual semiconductor chips through the substrate and the interposer between the semiconductor chips and the substrate, every time it passes through a node, the voltage decreases, resulting in a significant deterioration in a power transmission efficiency.

Therefore, it is desirable to develop a new package technology that may solve this problem.

### SUMMARY OF THE DISCLOSURE

A power distribution structure including a power distribution module (PDM) and a surface mounting device (SMD), and a composite interposer including a redistribution structure on the power distribution structure may be disposed between the semiconductor chips and the substrate.

A semiconductor package according to an embodiment includes an interposer including a power distribution structure, and a redistribution structure on the power distribution structure; a first semiconductor die on the interposer; and a second semiconductor die on the interposer, wherein the power distribution structure may include a power distribution module connected to a bottom surface of the redistribution structure; a plurality of conductive posts connected to the bottom surface of the redistribution structure; and a molding material molding the power distribution module and the plurality of conductive posts.

A semiconductor package according to an embodiment includes an interposer including a power distribution structure and a redistribution structure on the power distribution structure; a plurality of external connection members connected to a bottom surface of the interposer; a first semiconductor die on the interposer; and a second semiconductor die on the interposer, wherein the power distribution structure may include a power distribution module connected to a bottom surface of the redistribution structure; a surface mounting device connected to the bottom surface of the redistribution structure; a plurality of conductive posts connected to the bottom surface of the redistribution structure, wherein each conductive post of the plurality of conductive posts electrically connects the redistribution structure to an external connection member of the plurality of external connection members; and a molding material for molding the side surface of the plurality of conductive posts, the power distribution module, and the surface mounting device.

A method of manufacturing a semiconductor package according to an embodiment includes forming a redistribution structure on a carrier; forming a plurality of conductive posts on a first surface of the redistribution structure; mounting a power distribution module on the first surface of the redistribution structure; molding the power distribution module and the plurality of conductive posts with a first molding material on the first surface of the redistribution structure; removing the carrier from the redistribution structure; and mounting a logic die and a memory die on a second surface that is an opposite side to the first surface of the redistribution structure.

The power distribution structure including the power distribution module (PDM) and the surface mounting device (SMD), and the composite interposer including the redistribution structure on the power distribution structure may be disposed between the semiconductor chips and the substrate.

As a result, it is possible to significantly shorten the power transmission path from the power distribution module (PDM) and the surface mounting device (SMD) to the individual semiconductor chip, thereby removing a parasitic resistance in the substrate, increasing a power efficiency, and improving a power control response time.

### BRIEF DESCRIPTION OF THE DRAWINGS

FIG. 1 is a cross-sectional view showing a semiconductor package according to an example embodiment.

FIG. 2 to FIG. 12 are cross-sectional views showing a method of manufacturing a semiconductor package according to an example embodiment.

### DETAILED DESCRIPTION OF THE EMBODIMENTS

Hereinafter, example embodiments of the inventive concept will be described in detail with reference to the attached drawings so that the person of ordinary skill in the art may easily implement the inventive concept. However, the inventive concept may be modified in various ways and is not limited to the examples described herein.

In the drawings, elements irrelevant to the description of the inventive concept are omitted for simplicity of explanation, and like reference numerals designate like elements throughout the specification.

Further, since sizes and thicknesses of constituent members shown in the accompanying drawings are arbitrarily given for better understanding and ease of description, the inventive concept is not limited to the illustrated sizes and thicknesses.

Throughout the specification, when it is described that a part is “connected” to another part, the part may be “directly connected” to the other element or “connected” to the other part through a third part (e.g., intervening elements may be present). In contrast, when an element is referred to as being “directly connected” or “directly coupled” to another element, or as “contacting” or “in contact with” another element (or using any form of the word “contact”), there are no intervening elements present at the point of contact.

In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, in the specification, the phrase “on a plane” means when an object portion is viewed from above, and the phrase “on a cross-section” means when a cross-section taken by vertically cutting an object portion is viewed from the side.

Hereinafter, a semiconductor package and a manufacturing method of a semiconductor package of an example embodiment will be described with reference to drawings.

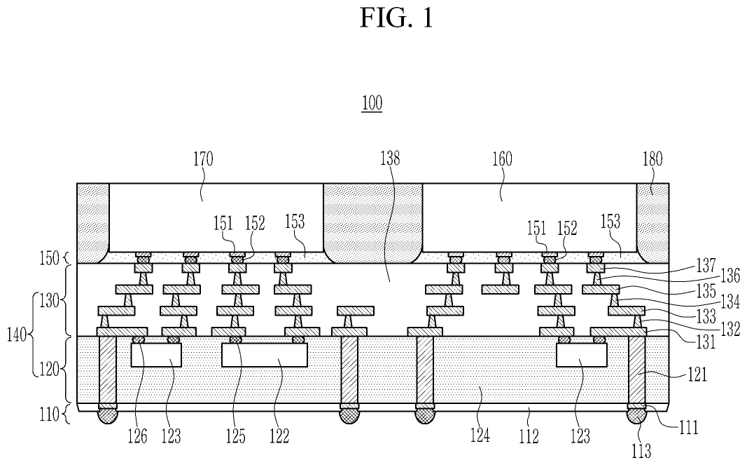

FIG. 1 is a cross-sectional view showing a semiconductor package 100 according to an example embodiment.

Referring to FIG. 1, the semiconductor package 100 may include an external connection structure 110, a composite interposer 140, an interconnect structure 150, a first semiconductor die 160, a second semiconductor die 170, and a molding second material 180.

In an embodiment, the semiconductor package 100 may include a 2.5D semiconductor package. In an embodiment, the semiconductor package 100 may include a fan out wafer level package (FOWLP) or a fan out panel level package (FOPLP).

The external connection structure 110 may be disposed on the bottom surface of the composite interposer 140. The external connection structure 110 may include conductive pads 111, an insulation layer 112, and external connection members 113. The conductive pads 111 may electrically connect the conductive posts 121 of the power distribution structure 120 to the external connection members 113. Each conductive pad 111 may contact one of the conductive posts 121 and a corresponding one of the external connection members 113. The insulation layer 112 may include a plurality of openings for a soldering. The insulation layer 112 may prevent the external connection members 113 from being short-circuited with each other. The external connection members 113 may electrically connect the semiconductor package 100 to a substrate (not shown) or an external device (not shown). An upper surface of the insulation layer 112 may be at a higher level than upper surfaces of the external connection members 113, and a bottom surface of the insulation layer 112 may be at a lower level than bottom surfaces of the external connection members 113. For example, bottom surfaces of the external connection members 113 may be recessed from the bottom surface of the insulation layer 112.

The composite interposer 140 may include a power distribution structure 120 and a redistribution structure 130. The composite interposer 140 serves as an intermediate medium electrically connecting the first semiconductor die 160 and the second semiconductor die 170 having an I/O of a fine pitch to a substrate (not shown) having an I/O of a normal pitch.

The power distribution structure 120 may include conductive posts 121, a power distribution module (PDM) 122, a surface mounting device (SMD) 123, and a first molding material 124. The external connection structure 110 may be disposed on the bottom surface of the power distribution structure 120. The redistribution structure 130 may be disposed on the upper surface of the power distribution structure 120. In example embodiments, the surface mounting device (SMD) 123 may be a plurality of a surface mounting devices (SMD) 123.

The conductive posts 121 may be disposed between the conductive pads 111 of the external connection structure 110 and the first redistribution lines 131 of the redistribution structure 130. The conductive posts 121 may electrically connect the first redistribution lines 131 of the redistribution structure 130 to the conductive pads 111 of the external connection structure 110. In example embodiments, upper surfaces of the conductive posts 121 may contact bottom surfaces of the first redistribution lines 131, and bottom surfaces of the conductive posts 121 may contact upper surfaces of the conductive pads 111. The conductive posts 121 may be disposed to penetrate the first molding material 124. The side surfaces of the conductive posts 121 may be surrounded by the first molding material 124. For example, the first molding material 124 may contact the side surfaces of the conductive posts 121.

The power distribution module (PDM) 122 may be disposed on the bottom surface of the first redistribution lines 131 of the redistribution structure 130. The power distribution module (PDM) 122 may be directly electrically connected to the first redistribution lines 131 of the redistribution structure 130. In an embodiment, the power distribution module (PDM) 122 may be electrically connected only through the first redistribution lines 131 of the redistribution structure 130. The power distribution module (PDM) 122 may be embedded in the first molding material 124 except for a portion in contact with the bottom surface of the first redistribution lines 131. For example, an upper surface of the power distribution module (PDM) 122 may be lower than an upper surface of the first molding material 124. In example embodiments, the first molding material 124 may surround the power distribution module (PDM) 122, and may contact a bottom surface, side surfaces, and a portion of the upper surface of the power distribution module (PDM) 122. The power distribution module (PDM) 122 may include connection members 125. In an embodiment, the connection members 125 may include micro bumps. The connection members 125 may electrically connect the power distribution module (PDM) 122 to the first redistribution lines 131 of the redistribution structure 130. For example, the connection members 125 may be disposed between the power distribution module (PDM) 122 and the first redistribution lines 131, and may contact the power distribution module (PDM) 122 and the first redistribution lines 131. In example embodiments, the first molding material 124 may surround side surfaces of the connection members 125, and may contact the side surfaces of the connection members 125.

The power distribution module (PDM) 122 is a device that supplies a power to semiconductor chips. The power distribution module (PDM) 122 has a function of distributing a single power supply supplied from the outside of the semiconductor package differently according to the semiconductor chips and supplying the distributed power to each of the semiconductor chips. For example, the power distribution module (PDM) 122 may receive power from a single power source, and distribute the received power to the semiconductor chips based on individual power requirements of the semiconductor chips. In an embodiment, the power distribution module (PDM) 122 may include at least one of a controller, a buck converter, a capacitor, a resistor, and an inductor. In an embodiment, the power distribution module (PDM) 122 may include a regulator.

The surface mounting device (SMD) 123 may be disposed on the bottom surface of the first redistribution line 131 of the redistribution structure 130. The surface mounting device (SMD) 123 may be directly electrically connected to the first redistribution line 131 of the redistribution structure 130. In an embodiment, the surface mounting device (SMD) 123 may be electrically connected only through the first redistribution line 131 of the redistribution structure 130. The surface mounting device (SMD) 123 may be embedded in the first molding material 124 except for a portion in contact with the bottom surface of the first redistribution line 131. For example, an upper surface of the surface mounting device (SMD) 123 may be lower than an upper surface of the first molding material 124. In example embodiments, the first molding material 124 may surround the surface mounting device (SMD) 123, and may contact a bottom surface, side surfaces, and a portion of the upper surface of the surface mounting device (SMD) 123. The surface mounting device (SMD) 123 may provide additional functions or a programming to the entire semiconductor package 100. In an embodiment, the surface mounting device (SMD) 123 may include at least one of a resistor, an inductor, a capacitor, and a jumper. The surface mounting device (SMD) 123 may include connection members 126. In an embodiment, the connection members 126 may include micro bumps. The connection members 126 may electrically connect the surface mounting device (SMD) 123 to the first redistribution lines 131 of the redistribution structure 130. For example, the connection members 126 may be disposed between the surface mounting device (SMD) 123 and the first redistribution lines 131, and may contact the surface mounting device (SMD) 123 and the first redistribution lines 131. In example embodiments, the first molding material 124 may surround side surfaces of the connection members 126, and may contact the side surfaces of the connection members 126.

In an embodiment, the surface mounting device (SMD) 123 may include an integrated stack capacitor (ISC) chip. The integrated stack capacitor (ISC) chip is a chip including a capacitor structure that is continuously extended in a vertical cylinder structure in which tens of thousands or more are arranged. The integrated stack capacitor (ISC) chip may suppress a power noise in a high frequency band of hundreds of MHz and has a much larger capacitance density than a multilayer ceramic capacitor (MLCC) or a land side capacitor (LSC). By including these integrated stack capacitor (ISC) chips in the composite interposer 140, a power transmission path to the first semiconductor die 160 and the second semiconductor die 170 may be significantly shortened, and a power integrity (PI) of the semiconductor package 100 may be improved.

The first molding material 124 may be disposed between the external connection structure 110 and the redistribution structure 130, and may mold the side surface of the conductive posts 121, the power distribution module (PDM) 122, and the surface mounting device (SMD) 123.

In the power distribution structure 120 including the power distribution module (PDM) 122 that distributes the single supply power supplied from the outside of the semiconductor package differently according to the semiconductor chips, the input voltage of the power distribution structure 120 may be higher than the output voltage of the power distribution structure 120, and the output current of the power distribution structure 120 may be higher than the input current of the power distribution structure 120.

According to the present disclosure, the power transmission path from the power distribution module (PDM) 122 and the surface mounting device (SMD) 123 to the first semiconductor die 160 and the second semiconductor die 170 may be greatly shortened, it may remove a parasitic resistance in the substrate, increase a power efficiency, and improve a power control response time.

The redistribution structure 130 may be disposed on the power distribution structure 120. The redistribution structure 130 may include a dielectric material layer 138. In addition, the redistribution structure 130 may include first redistribution lines 131, first redistribution vias 132, second redistribution lines 133, second redistribution vias 134, third redistribution lines 135, third redistribution vias 136, and fourth redistribution lines 137, which are disposed within the dielectric material layer 138. In another embodiment, the redistribution structure 130 including fewer or greater numbers of redistribution lines and redistribution vias is included within the scope of the present disclosure.

The dielectric material layer 138 may protect and insulate the first redistribution lines 131, the first redistribution vias 132, the second redistribution lines 133, the second redistribution vias 134, the third redistribution lines 135, the third redistribution vias 136, and the fourth redistribution lines 137. A first molding material 124 may be disposed under the bottom surface of the dielectric material layer 138, and an insulating member 153 and a second molding material 180 may be disposed on the upper surface of the dielectric material layer 138. For example, the first molding material 124 may contact the bottom surface of the dielectric material layer 138, and the insulating member 153 and the second molding material 180 may contact the upper surface of the dielectric material layer 138.

The first redistribution lines 131 may be disposed between the first redistribution vias 132 and the conductive posts 121, between the first redistribution vias 132 and the power distribution module (PDM) 122, and between the first redistribution vias 132 and the surface mounting device (SMD) 123. The first redistribution lines 131 may electrically connect the first redistribution vias 132 to the conductive posts 121, the power distribution module (PDM) 122, and the surface mounting device (SMD) 123 in a horizontal direction. The first redistribution vias 132 may be disposed between the second redistribution lines 133 and the first redistribution lines 131. The first redistribution vias 132 may electrically connect the second redistribution lines 133 to the first redistribution lines 131 in a vertical direction. The second redistribution lines 133 may be disposed between the second redistribution vias 134 and the first redistribution vias 132. The second redistribution lines 133 may electrically connect the second redistribution vias 134 to the first redistribution vias 132 in a horizontal direction. The second redistribution vias 134 may be disposed between the third redistribution lines 135 and the second redistribution lines 133. The second redistribution vias 134 may electrically connect the third redistribution lines 135 to the second redistribution lines 133 in a vertical direction. The third redistribution lines 135 may be disposed between the third redistribution vias 136 and the second redistribution vias 134. The third redistribution lines 135 may electrically connect the third redistribution vias 136 to the second redistribution vias 134 in a horizontal direction. The third redistribution vias 136 may be disposed between the fourth redistribution lines 137 and the third redistribution lines 135. The third redistribution vias 136 may electrically connect the fourth redistribution lines 137 to the third redistribution lines 135 in a vertical direction. The fourth redistribution lines 137 may be disposed between the connection members 152 of the interconnect structure 150 and the third redistribution vias 136. The fourth redistribution lines 137 may electrically connect the connection members 152 of the interconnect structure 150 to the third redistribution vias 136. In an embodiment, the first redistribution vias 132, the second redistribution vias 134, and the third redistribution vias 136 may have the width of the uppermost part smaller than the width of the lowermost part. For example, each of the first redistribution vias 132, the second redistribution vias 134, and the third redistribution vias 136 may have a tapered shape.

The first semiconductor die 160 may be disposed on the redistribution structure 130 of the composite interposer 140. The first semiconductor die 160 may be electrically connected to the redistribution structure 130 by the connection pads 151 and the connection members 152 of the interconnect structure 150. For example, a bottom surface of the first semiconductor die 160 may contact the connection pads 151. In an embodiment, the first semiconductor die 160 may include a logic die. In an embodiment, the first semiconductor die 160 may include a system on chip (SoC). In an embodiment, the first semiconductor die 160 may include at least one of a central processing unit (CPU), a graphic processing unit (GPU), a memory, a controller, a codec, a sensor, and a communication unit.

The second semiconductor die 170 may be disposed on the redistribution structure 130 of the composite interposer 140. The second semiconductor die 170 may be electrically connected to the redistribution structure 130 by the connection pads 151 and the connection members 152 of the interconnect structure 150. For example, a bottom surface of the second semiconductor die 170 may contact the connection pads 151. The second semiconductor die 170 may be disposed side by side with the first semiconductor die 160. In an embodiment, the second semiconductor die 170 may include a high bandwidth memory (HBM). The high-bandwidth memory (HBM) is a high performance three-dimensional 3D stacked dynamic random access memory (DRAM). The high-bandwidth memory (HBM) may be manufactured by performing a hybrid bonding or by vertically stacking memory dies on a buffer chip by using micro bumps to form a single memory stack.

The interconnect structure 150 may be disposed between the first semiconductor die 160 and the redistribution structure 130 and between the second semiconductor die 170 and the redistribution structure 130. The interconnect structure 150 may include connection pads 151, connection members 152, and an insulating member 153. The connection pads 151 may be disposed between the first semiconductor die 160 and the connection members 152 and between the second semiconductor die 170 and the connection members 152. The connection pads 151 may electrically connect the first semiconductor die 160 and the connection members 152, and the second semiconductor die 170 and the connection members 152. The connection members 152 may be disposed between the connection pads 151 and the fourth redistribution lines 137 of the redistribution structure 130. The connection members 152 may electrically connect the connection pads 151 and the fourth redistribution lines 137 of the redistribution structure 130. In an embodiment, the connection members 152 may include micro bumps. The insulating member 153 may surround and protect the connection pads 151 and the connection members 152 between the first semiconductor die 160 and the second semiconductor die 170. In an embodiment, the insulating member 153 may include a non-conductive film (NCF).

The second molding material 180 may be disposed on the redistribution structure 130 and mold the insulating member 153, the first semiconductor die 160, and the second semiconductor die 170. The upper surface of the first semiconductor die 160 and the upper surface of the second semiconductor die 170 may be externally exposed from the second molding material 180. For example, upper surfaces of the second semiconductor die 170 and the first semiconductor die 160 may be coplanar.

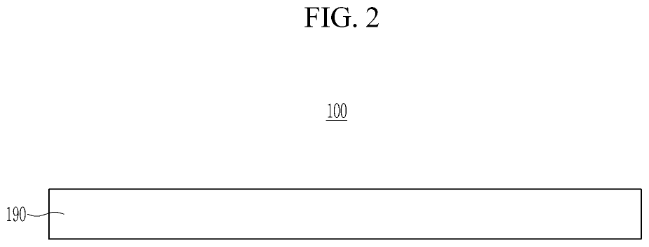

FIG. 2 to FIG. 12 are cross-sectional views showing a method of manufacturing a semiconductor package 100 according to an example embodiment.

FIG. 2 is a cross-sectional view showing a step of providing a carrier 190.

Referring to FIG. 2, first, the carrier 190 may be provided. In an embodiment, the carrier 190 may be formed of or include a silicon-based material such as glass or silicon oxide, an organic material, or another material such as aluminum oxide, any combination of these materials, and the like.

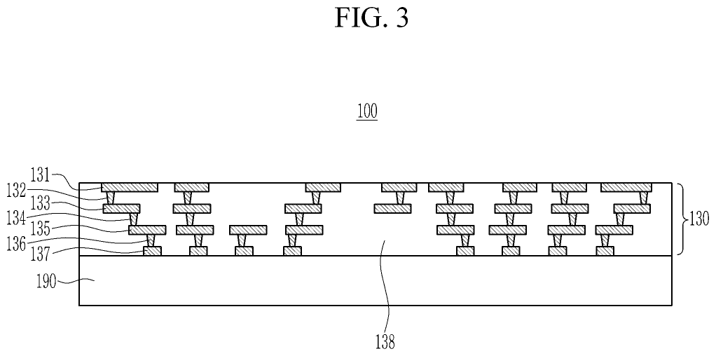

FIG. 3 is a cross-sectional view showing a step of forming a redistribution structure 130 on the carrier 190.

Referring to FIG. 3, a dielectric material layer 138 may be formed on the carrier 190. In an embodiment, the dielectric material layer 138 may include a photosensitive dielectric (a photo imageable dielectric (PID)) used in the redistribution process. The photo imageable insulator is a material that may form fine patterns by applying a photolithography process. As an embodiment, the photo imageable dielectric (PID) may include a polyimide-based photoactive polymer, a novolac-based photoactive polymer, polybenzoxazole, a silicon (Silicone)-based polymer, an acrylate-based polymer, or an epoxy-based polymer. In another embodiment, the dielectric material layer 138 is formed of an inorganic dielectric material such as silicon nitride, silicon oxide, or the like. In an embodiment, the dielectric material layer 138 may be formed by a chemical vapor deposition (CVD), atomic layer deposition (ALD), or plasma-enhanced chemical vapor deposition (PECVD) process.

After forming the dielectric material layer 138, openings may be formed by selectively etching the dielectric material layer 138, and fourth redistribution lines 137 may be formed by filling the openings with a conducting material.

Then, a dielectric material layer 138 may be additionally deposited on the fourth redistribution lines 137 and the dielectric material layer 138, the additionally deposited dielectric material layer 138 may be selectively etched to form via holes, and the via holes may be filled with a conducting material to form third redistribution vias 136.

Then, a dielectric material layer 138 may be additionally deposited on the third redistribution vias 136 and the dielectric material layer 138, and the additionally deposited dielectric material layer 138 may be selectively etched to form openings, and third redistribution lines 135 may be formed by filling a conducting material in the openings.

Next, a dielectric material layer 138 may be additionally deposited on the third redistribution lines 135 and the dielectric material layer 138, the additionally deposited dielectric material layer 138 may be selectively etched to form via holes, and the via holes may be filled with a conducting material to form second redistribution vias 134.

Then, a dielectric material layer 138 may be additionally deposited on the second redistribution vias 134 and the dielectric material layer 138, and the additionally deposited dielectric material layer 138 may be selectively etched to form openings, and the openings may be filled with a conducting material to form second redistribution lines 133.

Then, a dielectric material layer 138 may be additionally deposited on the second redistribution lines 133 and the dielectric material layer 138, the additionally deposited dielectric material layer 138 may be selectively etched to form via holes, and the via holes may be filled with a conducting material to form first redistribution vias 132.

Then, a dielectric material layer 138 may be additionally deposited on the first redistribution vias 132 and dielectric material layer 138, and the additionally deposited dielectric material layer 138 may be selectively etched to form openings, and first redistribution lines 131 may be formed by filling a conducting material in the openings.

After the redistribution structure 130 is completed on the carrier 190, a surface of the redistribution structure 130 far from the carrier 190 may be defined as a first surface, and a surface of the redistribution structure 130 in contact with the carrier 190 may be defined as a second surface. The second face may be defined as the opposite surface to the first face.

The width of the uppermost portion of each of the redistribution vias in the first redistribution vias 132, the second redistribution vias 134, and the third redistribution vias 136 may be greater than that of the lowermost portion. In the subsequent process, since a composite interposer 140 in which the redistribution structure 130 is formed is turned over to produce a final product, the width of the uppermost portion of each redistribution via in the first redistribution vias 132, the second redistribution vias 134, and the third redistribution vias 136 in the final product may be smaller than the width of the lowermost portion.

In an embodiment, the first redistribution lines 131, the first redistribution vias 132, the second redistribution lines 133, the second redistribution vias 134, the third redistribution lines 135, the third redistribution vias 136, and the fourth redistribution lines 137 may be formed of or include at least one of copper, aluminum, tungsten, nickel, and gold, tin, titanium and their alloys, respectively. In an embodiment, the first redistribution lines 131, the first redistribution vias 132, the second redistribution lines 133, the second redistribution vias 134, the third redistribution lines 135, the third redistribution vias 136, and the fourth redistribution lines 137 may be formed by performing a sputtering process. In another embodiment, the first redistribution lines 131, the first redistribution vias 132, the second redistribution lines 133, the second redistribution vias 134, the third redistribution lines 135, the third redistribution vias 136, and the fourth redistribution lines 137 may be formed by performing an electrolytic plating process after forming a seed metal layer.

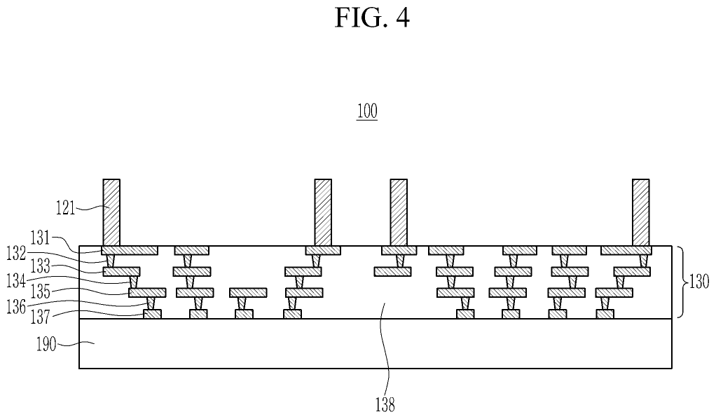

FIG. 4 is a cross-sectional view showing a step of forming conductive posts 121 on the first surface of the redistribution structure 130.

Referring to FIG. 4, the conductive posts 121 may be formed on the first redistribution lines 131 of the redistribution structure 130. In an embodiment, the conductive posts 121 may be formed by performing a sputtering process. In another embodiment, the conductive posts 121 may be formed by performing an electrolytic plating process after forming a seed metal layer. In an embodiment, the conductive posts 121 may be formed of or include at least one of copper, aluminum, tungsten, nickel, gold, silver, chromium, antimony, tin, titanium and alloys thereof.

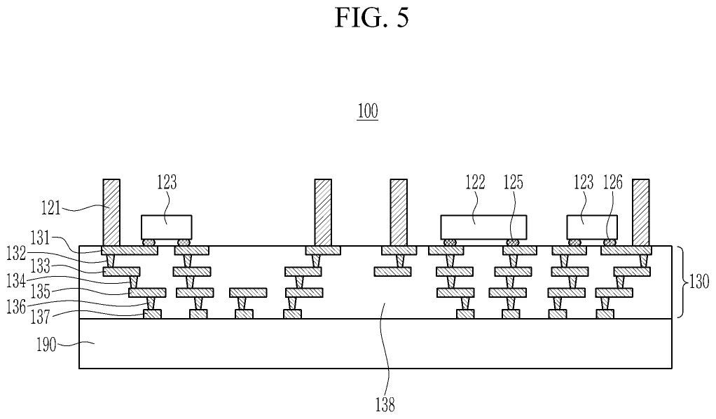

FIG. 5 is a cross-sectional view showing a step of mounting a power distribution module (PDM) 122 and a surface mounting device (SMD) 123 on the first surface of the redistribution structure 130.

Referring to FIG. 5, the power distribution module (PDM) 122 and the surface mounting device (SMD) 123 may be mounted on the first redistribution lines 131 of the redistribution structure 130. The power distribution module (PDM) 122 and the surface mounting device (SMD) 123 may be bonded on the first redistribution lines 131 by a flip chip bonding. The power distribution module (PDM) 122 and the surface mounting device (SMD) 123 may be disposed side by side with each other. As the connection members 125 of the bottom surface of the power distribution module (PDM) 122 and the connection members 126 of the bottom surface of the surface mounting device (SMD) 123 are bonded to the first redistribution lines 131 of the redistribution structure 130, the power distribution module (PDM) 122 and the redistribution structure 130, and the surface mounting device (SMD) 123 and the redistribution structure 130 may be electrically connected.

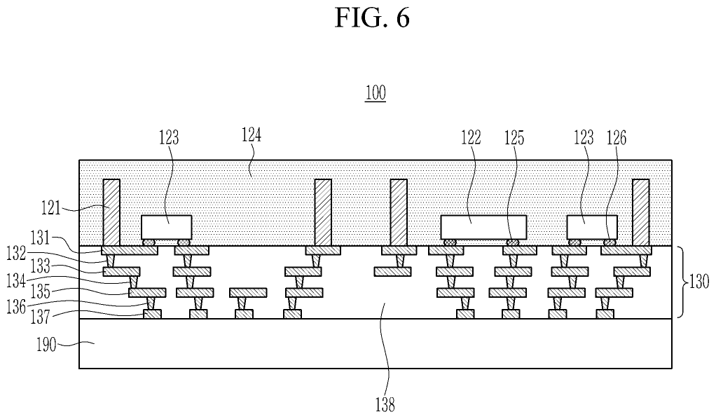

FIG. 6 is a cross-sectional view showing a step of molding the power distribution module (PDM) 122, the surface mounting device (SMD) 123, and the conductive posts 121 with a first molding material 124 on the first surface of the redistribution structure 130.

Referring to FIG. 6, on the redistribution structure 130, the power distribution module (PDM) 122, the surface mounting device (SMD) 123, and the conductive posts 121 may be molded with the first molding material 124. In an embodiment, the molding process with the first molding material 124 may include a compression molding or a transfer molding process. In an embodiment, the first molding material 124 may include an epoxy molding compound (EMC).

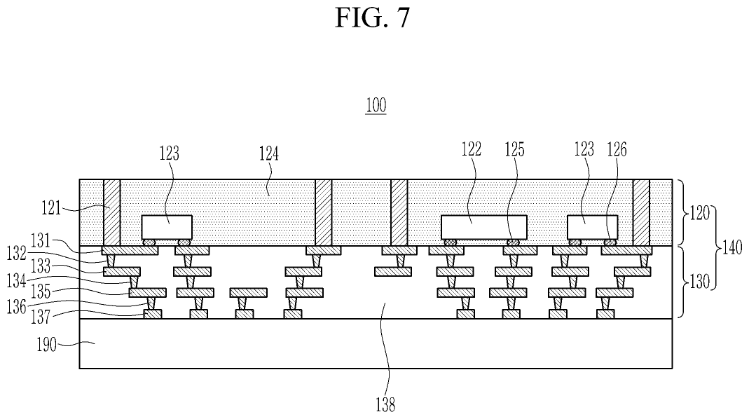

FIG. 7 is a cross-sectional view showing a step of planarizing the first molding material 124.

Referring to FIG. 7, a chemical mechanical polishing (CMP) may be performed to level the upper surface of the first molding material 124. The upper surface of the first molding material 124 may be planarized by applying the CMP process. After performing the CMP process, the upper surface of the conductive posts 121 may be exposed.

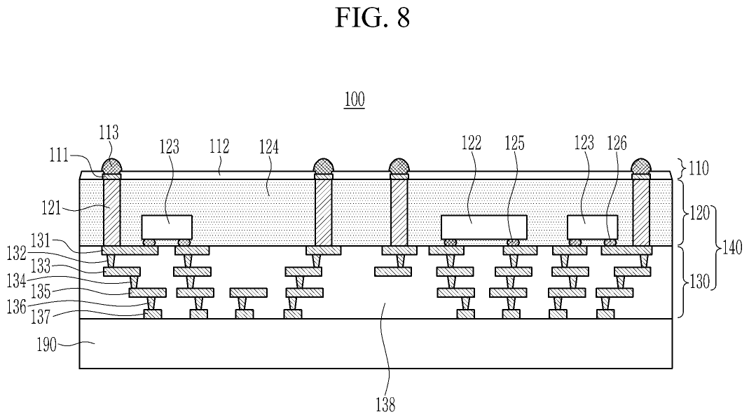

FIG. 8 is a cross-sectional view showing a step of forming an external connection structure 110 on the first molding material 124 and the exposed conductive posts 121.

Referring to FIG. 8, the external connection structure 110 may be formed on the first molding material 124 and the exposed conductive posts 121. An insulation layer 112 may be formed on the first molding material 124, conductive pads 111 may be formed on the exposed conductive posts 121, and external connection members 113 may be formed on the conductive pads 111. In an embodiment, the conductive pads 111 may be formed of or include at least one of copper, nickel, zinc, gold, silver, platinum, palladium, chromium, titanium and alloys thereof. In an embodiment, the insulation layer 112 may include a solder resist. In an embodiment, the external connection members 113 may be formed of or include at least one of tin, silver, lead, nickel, copper, or an alloy thereof. In an embodiment, the conductive pads 111 may be formed by performing a sputtering process, or an electrolytic plating process after forming a seed metal layer. In an embodiment, the insulation layer 112 may be formed with a CVD, ALD, or PECVD process.

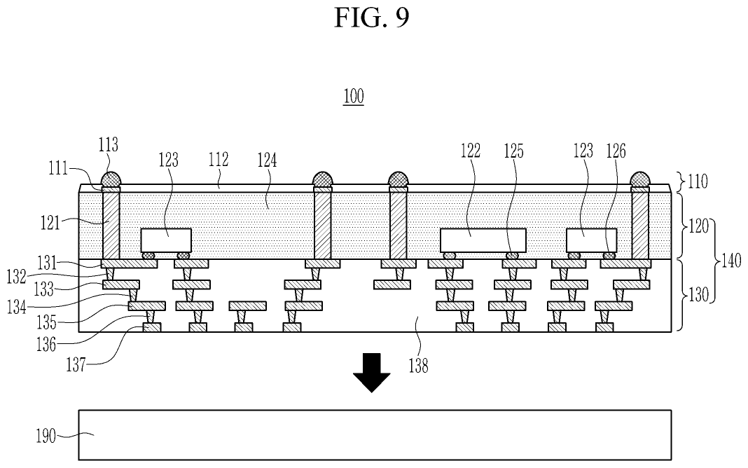

FIG. 9 is a cross-sectional view showing the step of removing the carrier 190 from the second side of the redistribution structure 130.

Referring to FIG. 9, the carrier 190 may be removed from the second side of the redistribution structure 130.

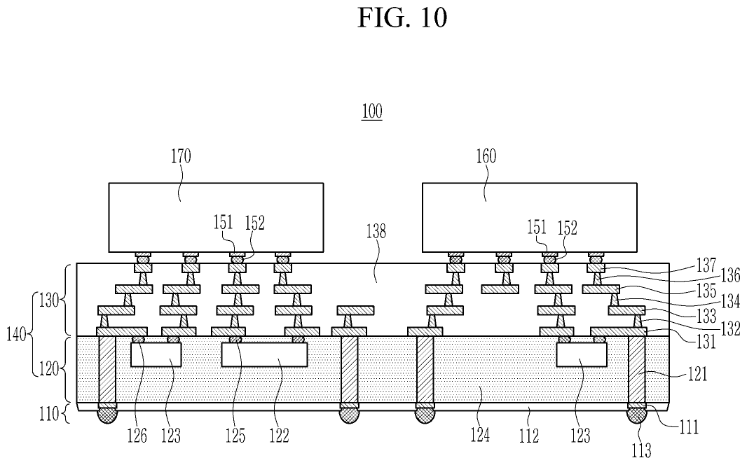

FIG. 10 is a cross-sectional view showing a step of mounting a first semiconductor die 160 and a second semiconductor die 170 on the second surface of the redistribution structure 130 of the composite interposer 140.

Referring to FIG. 10, the first semiconductor die 160 and the second semiconductor die 170 may be mounted on the second surface of the redistribution structure 130. The first semiconductor die 160 and the second semiconductor die 170 may be mounted on the second surface of the redistribution structure 130 by a flip chip bonding. As the connection members 152 of the first semiconductor die 160 and the second semiconductor die 170 are bonded to the fourth redistribution lines 137 of the redistribution structure 130, the first semiconductor die 160 and the redistribution structure 130, and the second semiconductor die 170 and the redistribution structure 130 may be electrically connected. In an embodiment, the connection members 152 may include a micro bump or a solder ball. In an embodiment, the connection members 152 may include at least one of tin, silver, lead, nickel, copper and alloys thereof.

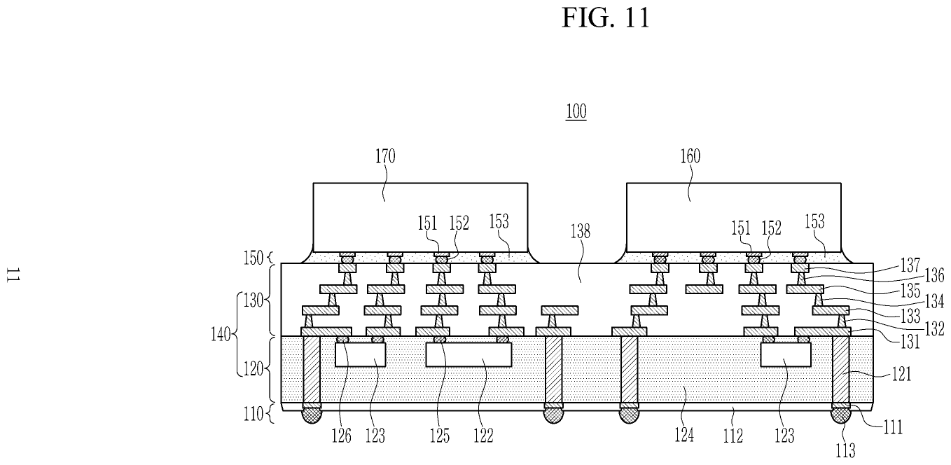

FIG. 11 is a cross-sectional view illustrating a step of disposing an insulating member 153 between the redistribution structure 130 and the first semiconductor die 160, and between the redistribution structure 130 and the second semiconductor die 170.

Referring to FIG. 11, the insulating member 153 may be disposed between the redistribution structure 130 and the first semiconductor die 160, and between the redistribution structure 130 and the second semiconductor die 170, thereby smoothing the stress between the redistribution structure 130 and the first semiconductor die 160, and between the redistribution structure 130 and the second semiconductor die 170. The insulating member 153 may surround the connection pads 151 and the connection members 152. In an embodiment, the insulating member 153 may be formed of or include a non-conductive film (NCF). In an embodiment, the insulating member 153 may be formed of or include a molded under-fill (MUF).

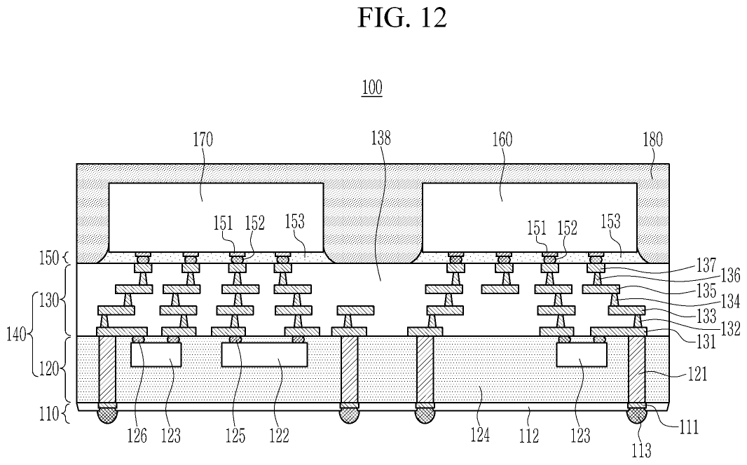

FIG. 12 is a cross-sectional view showing a step of molding the insulating members 153, the first semiconductor die 160, and the second semiconductor die 170 with the second molding material 180 on the second surface of the redistribution structure 130.

Referring to FIG. 12, on the second surface of the redistribution structure 110, the insulating members 153, the first semiconductor die 160, and the second semiconductor die 170 may be molded with the second molding material 180. In an embodiment, the molding process with the second molding material 180 may include a compression molding or a transfer molding process. In an embodiment, the second molding material 180 may be formed of or include an epoxy molding compound (EMC).

While this inventive concept has been described in connection with what is presently considered to be example embodiments, it is to be understood that the invention is not limited to the disclosed embodiments. On the contrary, it is intended to cover various modifications and equivalent arrangements included within the spirit and scope of the appended claims.

What is claimed is:

1. A semiconductor package comprising:
an interposer including a power distribution structure, and a redistribution structure on the power distribution structure;
a first semiconductor die on the interposer; and
a second semiconductor die on the interposer,
wherein the power distribution structure includes:
a power distribution module connected to a bottom surface of the redistribution structure;
a plurality of conductive posts connected to the bottom surface of the redistribution structure; and
a molding material molding the power distribution module and the plurality of conductive posts.

2. The semiconductor package of claim 1, wherein the power distribution module includes at least one of a controller, a buck converter, a capacitor, a resistor, and an inductor.

3. The semiconductor package of claim 1, wherein the power distribution module includes a regulator.

4. The semiconductor package of claim 1, wherein an input voltage of the power distribution structure is higher than an output voltage of the power distribution structure.

5. The semiconductor package of claim 1, wherein an output current of the power distribution structure is higher than an input current of the power distribution structure.

6. The semiconductor package of claim 1,
wherein the redistribution structure includes a plurality of redistribution lines, and
wherein the power distribution module is electrically connected only through the redistribution lines disposed at the lowest level of the plurality of redistribution lines.

7. The semiconductor package of claim 1,
wherein the redistribution structure includes a plurality of redistribution vias, and
wherein each redistribution via among the plurality of redistribution vias has an uppermost width smaller than a lowermost width.

8. The semiconductor package of claim 1, wherein the second semiconductor die is disposed side by side with the first semiconductor die.

9. A semiconductor package comprising:
an interposer including a power distribution structure and a redistribution structure on the power distribution structure;
a plurality of external connection members connected to a bottom surface of the interposer;
a first semiconductor die on the interposer; and
a second semiconductor die on the interposer,
wherein the power distribution structure includes:
a power distribution module connected to a bottom surface of the redistribution structure;
a surface mounting device connected to the bottom surface of the redistribution structure;
a plurality of conductive posts connected to the bottom surface of the redistribution structure, wherein each conductive post of the plurality of conductive posts electrically connects the redistribution structure to an external connection member of the plurality of external connection members; and
a molding material for molding side surfaces of the plurality of conductive posts, the power distribution module, and the surface mounting device.

10. The semiconductor package of claim 9, wherein the surface mounting device includes an integrated stack capacitor (ISC) chip.

11. The semiconductor package of claim 9, wherein the first semiconductor die includes a system on chip (SoC).

12. The semiconductor package of claim 9, wherein the second semiconductor die includes a high bandwidth memory (HBM).

13. The semiconductor package of claim 9, wherein the molding material includes an epoxy molding compound (EMC).

14. The semiconductor package of claim 9,
wherein the redistribution structure includes a plurality of redistribution lines, and
wherein the surface mounting device is electrically connected only through the redistribution lines disposed at the lowest level of the plurality of redistribution lines.

15. The semiconductor package of claim 9, further comprising:
an interconnect structure between the interposer and the first semiconductor die, and between the interposer and the second semiconductor die.

16. The semiconductor package of claim 15, wherein the interconnect structure includes connection members and an insulating member surrounding the connection members.

17. The semiconductor package of claim 16, wherein the connection members include micro bumps.

18. The semiconductor package of claim 16, wherein the insulating member includes a non-conductive film (NCF).

19. A method of manufacturing a semiconductor package comprising:
forming a redistribution structure on a carrier;
forming a plurality of conductive posts on a first surface of the redistribution structure;
mounting a power distribution module on the first surface of the redistribution structure;
molding the power distribution module and the plurality of conductive posts with a first molding material on the first surface of the redistribution structure;
removing the carrier from the redistribution structure; and
mounting a logic die and a memory die on a second surface that is an opposite side to the first surface of the redistribution structure.

20. The method of manufacturing the semiconductor package of claim 19, further comprising:
molding the logic die and the memory die with a second molding material on the second surface of the redistribution structure.
